(19) United States
(12) Patent Application Publication
(10) Pub. No.: US 2021/0180181 A1
(43) Pub. Date: Jun. 17, 2021

(54) VAPOR DEPOSITION CARRIER PLATE AND METHOD FOR PERFORMING VAPOR DEPOSITION ON SUBSTRATE BY USING VAPOR DEPOSITION CARRIER PLATE

(71) Applicant: Zhiqiao LIU, Wuhan (CN)

(72) Inventor: Zhiqiao LIU, Wuhan (CN)

(21) Appl. No.: 16/349,280

(22) PCT Filed: Jan. 11, 2019
(86) PCT No.: PCT/CN2019/071327

§ 371 Date: May 13, 2019

(30) Foreign Application Priority Data
Nov. 26, 2018 (CN) 201811416418.5

(51) Int. Cl. C23C 14/50; C23C 14/24; H01L 51/00

(52) U.S. Cl. CPC C23C 14/50; H01L 51/001; C23C 14/24

(57) ABSTRACT

The present invention discloses a vapor deposition carrier plate and a method for performing vapor deposition on a substrate by using such vapor deposition carrier plate. The vapor deposition carrier plate includes a carrier plate body, having a loading surface configured to load a substrate, wherein the substrate includes a lateral portion, a transitional region and a display region; and a plurality of protrusions, detachably fixed on the loading surface of the carrier plate body; wherein the protrusions include first protrusions, at least one of the first protrusions corresponding to the transitional region; and second protrusions, corresponding to the display region. According to the vapor deposition carrier plate, in order to alleviate the risk of the vapor deposition process, the carrier plate body and the protrusions are designed in a separable combined manner, thereby effectively reducing the probability of bonding, and reducing the risk of fragmentation.

### FIELD OF INVENTION

The present invention relates to the technical field of a vapor deposition device and manufacturing of an organic light-emitting diode (OLED) substrate, and in particular to a vapor deposition carrier plate and a method for performing vapor deposition on a substrate by using the vapor deposition carrier plate.

### BACKGROUND OF INVENTION

With the development of technology, the size of a substrate of an organic light-emitting diode (OLED) display device is larger and larger. During a vapor deposition process of the substrate, since the size of the substrate is too large, after the substrate is attached to a vapor deposition carrier plate (touch plate), the curvature of the substrate is also increased. Therefore, the risk of fragmentation is greatly increased, and the defect rate of OLED products due to display unevenness is also greatly increased. In the existing vapor deposition carrier plate (touch plate), protrusions and a carrier plate body are integrally designed. Therefore, positions and sizes of the protrusions cannot be adjusted according to actual conditions. For example, when the arrangement manner of an upper surface of the substrate is changed, and the design of a metal mask is changed, the attachment condition of the substrate and the metal mask is changed, but the fixed protrusions cannot be adjusted accordingly. The bonding phenomenon between the substrate and the vapor deposition carrier plate (touch plate) in a vacuum vapor deposition chamber and the problem of uneven attachment gaps between the substrate and the metal mask are more and more serious.

### SUMMARY OF INVENTION

### Technical Problem

The technical problem to be solved by the present invention is to provide a vapor deposition carrier plate and a method for performing vapor deposition on the substrate by using the vapor deposition carrier. By the structure in which protrusions and a carrier plate body are separated, it is convenient to substitute matching protrusions in positions corresponding to the substrate according to an actual vapor deposition condition, thereby alleviating the bonding phenomenon of the substrate and the problems of display unevenness of a display device and the like.

### Solution

In order to solve the above technical problem, there is provided a vapor deposition carrier plate, including: a carrier plate body, the carrier plate body including a loading surface configured to load a substrate, wherein the substrate includes a lateral portion, a transitional region and a display region; and a plurality of protrusions, the protrusions being detachably fixed on the loading surface of the carrier plate body. The protrusions include: a plurality of first protrusions, at least one of the first protrusions being disposed corresponding to the transitional region; and second protrusions disposed corresponding to the display region.

In one embodiment of the present invention, the first protrusions and the second protrusions are both of a lattice arrangement structure. A distribution density of the second protrusions is less than a distribution density of the first protrusions.

In one embodiment of the present invention, a height of the second protrusions is less than a height of the first protrusions.

The height of the first protrusions is 40 to 50 micrometers; and the height of the second protrusions is 35 to 45 micrometers.

In one embodiment of the present invention, the protrusions are in the shape of at least one of a prismatic table, a circular truncated cone, a cylinder and a prism.

In one embodiment of the present invention, an adhesive layer is disposed between the protrusions and the carrier plate body, and the protrusions are adhered and fixed to the carrier plate body by the adhesive layer.

In one embodiment of the present invention, the carrier plate body is provided with embedding grooves, and the protrusions are correspondingly engaged in the embedding grooves.

The present invention further provides a method for performing vapor deposition on a substrate by using a vapor deposition carrier plate. The method includes: providing the vapor deposition carrier plate, wherein the vapor deposition carrier plate includes a carrier plate body and a plurality of protrusions, the carrier plate body has a loading surface configured to load the substrate, and the protrusions include a plurality of first protrusions and a plurality of second protrusions; and providing a substrate, the substrate including a lateral portion, a transitional region, and a display region. At least one of the first protrusions is disposed corresponding to the transitional region, and the second protrusions are disposed corresponding to the display region.

In one embodiment of the present invention, the first protrusions and the second protrusions are both of a lattice arrangement structure, and a distribution density of the second protrusions is less than a distribution density of the first protrusions.

In one embodiment of the present invention, in a place where the transitional region meets the lateral portion of the substrate, a minimum distance between the transitional region and the closest one of the first protrusions is 7000 micrometers to 8000 micrometers.

In one embodiment of the present invention, the substrate is an organic light-emitting diode (OLED) display substrate.

### Beneficial Effects

According to the vapor deposition carrier plate and the method for performing vapor deposition on the substrate by using the vapor deposition carrier plate of the present invention, the probability of bonding and the risk of fragmentation can be effectively reduced by designing the carrier plate body and the protrusions as a separable combined structure. Meanwhile, the present invention also alleviates the problem that the substrate is unevenly attached to a metal mask due to the bending deformation of the substrate, thereby alleviating the darkening phenomenon of some products caused by coating offset. In addition, in view of the difference between an actual vapor deposition process and theoretical simulation, the actual attaching requirements are also different for different products. Therefore, according to the present invention, by the separable combined design of the carrier plate body and the protrusions, the protrusions meeting the actual requirements can be conveniently designed in real time, including flexible setting of the size, distribution position, number, angle, etc. of the protrusions, without a need to replace the entire vapor deposition carrier plate. Only the size, distribution position, number, etc. of the protrusions need to be adjusted to meet the vapor deposition requirements of different substrates.

### BRIEF DESCRIPTION OF DRAWINGS

To describe the technical solutions in the embodiments of the preset invention more clearly, the following briefly describes the accompanying drawings required for describing the embodiments. Apparently, the accompanying drawings in the following description show merely some embodiments of the present invention, and a person of ordinary skill in the art may still derive other drawings from these accompanying drawings without creative efforts.

The preset invention is further described with reference to the accompanying drawings and embodiments.

FIG. 1 is an exploded view of the structure of a vapor deposition carrier plate according to an embodiment of the present invention, and mainly shows an engagement manner of protrusions.

FIG. 2 is a structural top view of a vapor deposition carrier plate according to an embodiment of the present invention, and mainly shows the distribution condition of first protrusions and second protrusions.

FIG. 3 is a layered enlarged view of a circled part A of FIG. 2, and mainly shows a position relationship between the protrusions and each region of the substrate.

In the figures:
100 vapor deposition carrier plate
110 carrier plate body 120 protrusions
111 embedding groove 112 loading surface
121, 121′ first protrusion 122 second protrusion
200 substrate
210 lateral portion 220 transitional region
230 display region

### DETAILED DESCRIPTION OF PREFERRED EMBODIMENTS

The embodiments of the present invention are described in detail below. Examples of the embodiments are shown in the accompanying drawings. Throughout the specification, same or similar reference numerals represent same or similar elements or elements having same or similar functions. The embodiments described below with reference to the accompanying drawings are exemplary, and are merely used for explaining the present invention, but should not construed as limiting the present invention.

The following embodiments are described with reference to the accompanying drawings, and are used to exemplify particular embodiments that the present invention can be used to implement. Direction terms mentioned in the present invention such as “upper”, “lower”, “front”, “rear”, “left”, “right”, “top”, and “bottom” are only directions with reference to the accompanying drawings. Therefore, the used direction terms are intended to describe and understand the present invention, but are not intended to limit the present invention.

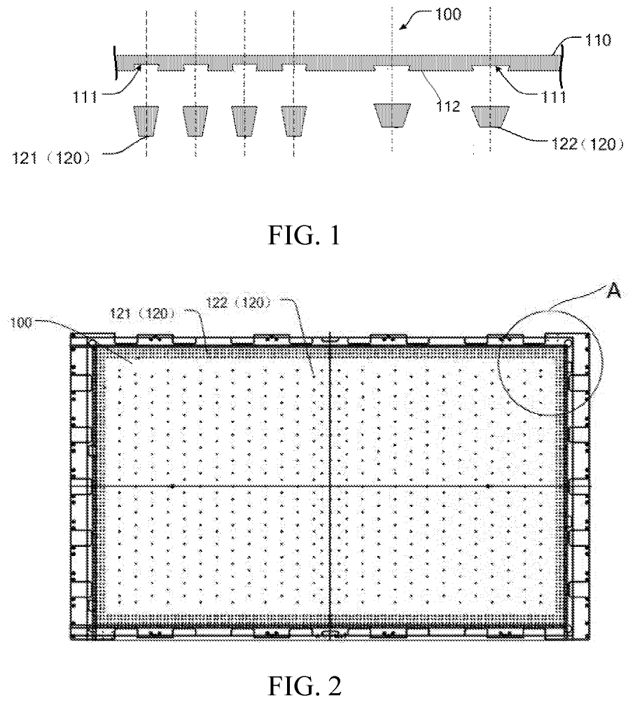

As shown in FIG. 1, in one embodiment, a vapor deposition carrier plate 100 according to the present invention includes a carrier plate body 110 and a plurality of protrusions 120.

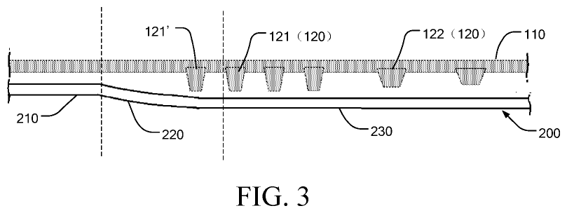

The carrier plate body 110 may be a rectangular metal plate, and the size thereof is designed according to the size of the substrate 200 to match the substrate 200 (see FIG. 3). The carrier plate body 110 has a loading surface 112 configured to load the substrate 200.

As shown in FIG. 3, the substrate 200 is generally a glass substrate, and is generally in the shape of a rectangle, which is matched with the carrier plate body 110. In the present embodiment, the substrate 200 is an organic light-emitting diode (OLED) display substrate. The substrate 200 includes a lateral portion 210, a transitional region 220, and a display region 230. The transitional region 220 is connected to the lateral portion 210 of the substrate 200. The display region 230 is located in the middle region of the substrate and is connected to the connected to the transitional region 220.

As shown in FIG. 1, the protrusions 120 are detachably fixed on the loading surface 112 of the carrier plate body 110. During actual assembling, the protrusions 120 may be fixed on the carrier plate body 110 in a bonding or engaging manner. If the bonding manner is adopted, one adhesive layer may be added between the protrusions 120 and the carrier plate body 110. However, since during the vapor deposition, the adhesive layer may be softened by too high temperature, the vapor deposition process is affected. Therefore, in the present embodiment, the protrusions 120 are engaged the carrier plate body 110 by using an engagement manner. During specific design, one surface of the carrier plate body 110 facing the substrate 200 (on the loading surface 112) is provided with a plurality of embedding grooves 111 matched with the sizes of the corresponding protrusions 120, and then each protrusion 120 is correspondingly engaged in the embedding groove 111.

The shape and the size of the protrusions 120 may also be adjusted according to actual conditions. Generally, the shape of the protrusions 120 may be designed into the shape of at least one of a prismatic table, a circular truncated cone, a cylinder, and a prism. As shown in FIG. 1, in the present embodiment, a trapezoidal table structure in the shape of the prismatic table is used. The bottom surface of the protrusion 120 having a larger area is embedded in the embedding groove 111, so that the protrusion 120 is kept fixed without displacing or rotating.

As shown in FIG. 3, in order to adapt to the actual conditions of the positions of different regions on the substrate 200, in general, due to uneven heating during vapor deposition, the display region 230 is heated more, and the lateral portion 210 and the transitional region 220 are heated less. Therefore, relatively large deformation generally occurs in the transitional region 220. Thus, as shown in FIG. 2, when the protrusions 120 are designed, the protrusions 120 are divided into a plurality of first protrusions 121 and a plurality of second protrusions 122. The first protrusions 121 and the second protrusions 122 are both of a lattice arrangement structure. The first protrusions 121 surround the second protrusions 122. A distribution density of the second protrusions 122 is less than a distribution density of the first protrusions 121. That is, the distance between the first protrusions 121 may be set to 5 to 11 mm. The distance between the second protrusions 122 may be set to 25 to 40 mm. The height of the protrusions 120 is adjusted according to actual conditions to optimize vapor deposition. In the present embodiment, the height of the second protrusions 122 is less than the height of the first protrusions 121. The height of the first protrusions 121 is 40 to 50 micrometers. The height of the second protrusions 122 is 35 to 45 micrometers. Such design is advantageous in preventing the substrate 200 from falling off to cause the fragmentation phenomenon when the substrate 200 is attached and bonded to the carrier plate body 110.

In the present embodiment, the protrusion 120 adopts a trapezoidal table structure, and includes at least two opposite side surfaces. The two opposite side surfaces are not parallel to each other but have an angle between them, and the angle generally may range from 110° to 120°. Meanwhile, one surface of the trapezoidal table protrusion 120 facing the substrate can have angle adjustment according to the actual needs.

Referring to FIG. 3, at least one of the first protrusions 121 is disposed corresponding to the transitional region 220 of the substrate 200. The second protrusions 122 is disposed corresponding to the display region 230 of the substrate 200. On the substrate 200, an edge of the display region 230 extends to the positions corresponding to the second protrusions 122. In a place where the transitional region 220 meets the lateral portion 210, the minimum distance between the transitional region 220 and the closest first protrusion 121′ is 7000 micrometers to 8000 micrometers. Such design is advantageous in alleviating the phenomenon of uneven attachment between the substrate 200 and a metal mask due to the bending deformation of the transitional region 220, thereby effectively preventing the phenomenon that the formed film of an upper film layer on the substrate 200 is relatively displaced.

Referring to FIG. 1 to FIG. 3, a method for performing vapor deposition on a substrate by using the vapor deposition carrier plate according to the present invention includes the following steps:

A vapor deposition carrier plate 100 is provided. The vapor deposition carrier plate 100 includes a carrier plate body 110 and a plurality of protrusions 120. The carrier plate body 110 has a loading surface 112 configured to load the substrate 200. The protrusions 120 include a plurality of first protrusions 121 and a plurality of second protrusions 122. The first protrusions 121 and the second protrusions 122 are both of a lattice arrangement structure. A distribution density of the second protrusions 122 is less than that of the first protrusions 121, and the first protrusions 121 surround the second protrusions 122.

A substrate 200 is provided. The substrate 200 includes a lateral portion 210, a transitional region 220, and a display region 230. At least one of the first protrusions 121 is disposed corresponding to the transitional region 220. The second protrusions 122 are disposed corresponding to the display region 230.

Of course, the above method may further include providing a metal mask attached to the substrate 200.

The present invention will be further described below in conjunction with the use process. Referring to FIG. 1 to FIG. 3, for example, when the vapor deposition carrier plate 100 according to the present embodiment is configured for vapor deposition for the first time, if it is found that since the height of the display region 230 is not enough due to part of the first protrusions 121, the substrate 200 and the vapor deposition carrier plate 100 are not well attached to each other, and thus the substrate 200 is fragmented/broken from falling off. Then during the next vapor deposition, the first protrusions 121 in such positions can be replaced so as to adapt to the requirements of the current substrate 200 in the vapor deposition process, and to prevent the substrate 200 from falling off. For another example, if it is found that since the arrangement density of the protrusions 120 at a certain area on the corresponding substrate 200 is too small, the deformation of the substrate 200 at such positions is too large, and the position of the formed film is caused to be relatively offset. Then during the next vapor deposition, one or multiple protrusions 120 may be additionally disposed in the corresponding region of the substrate 200 according to the present vapor deposition condition.

In summary, according to the vapor deposition carrier plate 100, the probability of bonding and the risk of fragmentation can be effectively reduced by designing the carrier plate body 110 and the protrusions 120 as a separable combined structure. Meanwhile, the problem that the substrate 200 is unevenly attached to the metal mask due to the bending deformation of the substrate 200 is alleviated, thereby alleviating the darkening phenomenon of some products caused by coating offset. In view of the difference between an actual vapor deposition process and theoretical simulation, the actual attachment requirements are also different for different products. Therefore, due to the separable combined design of the carrier plate body 110 and the protrusions 120, the protrusions 120 meeting the actual requirements can be conveniently designed in real time, including flexible setting of the size, distribution position, number, angle, etc. of the protrusions 120, without a need to replace the entire vapor deposition carrier plate 100. The present invention can meet the vapor deposition requirements of different substrates 200 by only adjusting the size, distribution position, number, etc. of the protrusions 120.

The above descriptions are merely preferred embodiments of the present invention, and are not intended to limit the present invention. Any modification, equivalent replacement and improvement made without departing from the spirit and principle of the present invention shall fall within the protection scope of the present invention.

What is claimed is:

1. A vapor deposition carrier plate, comprising:
a carrier plate body, the carrier plate body comprising a loading surface configured to load a substrate, wherein the substrate comprises a lateral portion, a transitional region, and a display region; and
a plurality of protrusions, the protrusions being detachably fixed on the loading surface of the carrier plate body;
wherein the protrusions comprise:
a plurality of first protrusions, at least one of the first protrusions being disposed corresponding to the transitional region; and
a plurality of second protrusions disposed corresponding to the display region.

2. The vapor deposition carrier plate according to claim 1, wherein the first protrusions and the second protrusions are both of a lattice arrangement structure, and a distribution density of the second protrusions is less than a distribution density of the first protrusions.

3. The vapor deposition carrier plate according to claim 1, wherein a height of the second protrusions is less than a height of the first protrusions;
the height of the first protrusions is 40 to 50 micrometers; and
the height of the second protrusions is 35 to 45 micrometers.

4. The vapor deposition carrier plate according to claim 1, wherein the protrusions are in the shape of at least one of a prismatic table, a circular truncated cone, a cylinder and a prism.

5. The vapor deposition carrier plate according to claim 1, wherein an adhesive layer is disposed between the protrusions and the carrier plate body, and the protrusions are adhered and fixed to the carrier plate body by the adhesive layer.

6. The vapor deposition carrier plate according to claim 1, wherein the carrier plate body is provided with embedding grooves, and the protrusions are correspondingly engaged in the embedding grooves.

7. A method for performing vapor deposition on a substrate by using a vapor deposition carrier plate, comprising:
providing the vapor deposition carrier plate of claim 1, wherein the vapor deposition carrier plate comprises a carrier plate body and a plurality of protrusions, the carrier plate body comprises a loading surface configured to load the substrate; and the protrusions comprise a plurality of first protrusions and a plurality of second protrusions; and
providing a substrate, the substrate comprising a lateral portion, a transitional region, and a display region; wherein the at least one of the first protrusions is disposed corresponding to the transitional region, and the second protrusions are disposed corresponding to the display region.

8. The method for performing vapor deposition on the substrate by using the vapor deposition carrier plate according to claim 7, wherein the first protrusions and the second protrusions are both of a lattice arrangement structure, and a distribution density of the second protrusions is less than a distribution density of the first protrusions.

9. The method for performing vapor deposition on the substrate by using the vapor deposition carrier plate according to claim 7, wherein in a place where the transitional region meets the lateral portion of the substrate, a minimum distance between the transitional region and the closest one of the first protrusions is 7000 micrometers to 8000 micrometers.

10. The method for performing vapor deposition on the substrate by using the vapor deposition carrier plate according to claim 7, wherein the substrate is an organic light-emitting diode (OLED) display substrate.
